(19) United States
(12) Patent Application Publication
(10) Pub. No.: US 2026/0173582 A1
(43) Pub. Date: Jun. 18, 2026

(54) METHOD OF MANUFACTURING AN OPTOELECTRONIC DEVICE

(71) Applicant: Commissariat à I'Énergie Atomique et aux Énergies Alternatives, Paris (FR)

(72) Inventors: Carole Pernel, Grenoble (FR); Simona Torrengo, Grenoble (FR); Julia Simon, Grenoble (FR)

(73) Assignee: Commissariat à I'Énergie Atomique et aux Énergies Alternatives, Paris (FR)

(21) Appl. No.: 19/416,325

(22) Filed: Dec. 11, 2025

(30) Foreign Application Priority Data
Dec. 17, 2024 (FR) FR2414283

(51) Int. Cl. H10H 20/01

(52) U.S. Cl. CPC H10H 20/01335

(57) ABSTRACT

A method for manufacturing an optoelectronic device, the method including the following successive steps: a) forming, on a support substrate, an electropolishing stack including:—a first sacrificial semiconductor layer; a second charge transport semiconductor layer; and a third semiconductor layer for protecting the second layer, the third layer being interposed between the first and second layers and having a doping level lower than those of the first and second layers; b) forming, on the side of a surface of the electropolishing stack opposite to the support substrate, an active gallium nitride diode stack; and c) removing the support substrate by electropolishing of the first layer.

### TECHNICAL FIELD

The present disclosure generally concerns optoelectronic devices. It more particularly aims at optoelectronic devices comprising a plurality of gallium nitride diodes and a circuit for controlling these diodes, as well as methods of manufacturing such devices.

### PRIOR ART

Optoelectronic devices comprising a plurality of gallium nitride diodes, for example gallium nitride light-emitting diodes (LEDs), and a circuit for controlling these diodes have been provided. Methods of manufacturing such devices have also been provided.

According to an approach, an active diode stack is formed on a first support substrate, for example made of silicon, coated with one or more buffer layers for the growth of the active diode stack. The active diode stack is then transferred onto a second substrate inside and on top of which the control circuit has been previously formed. The first substrate is then removed, for example by grinding of the silicon of the first substrate and then thinning of the growth buffer layer(s) by dry etching. The plurality of diodes is then formed from the active diode stack. According to another approach, the plurality of diodes is formed from the active diode stack prior to the step of transfer onto the second substrate.

However, existing optoelectronic devices and existing methods of manufacturing such devices suffer from various disadvantages. For example, the step of removing the support substrate comprises risks of damage to the active diode stack or to the plurality of diodes, depending on the considered approach. In particular, the thinning of the buffer layers by dry etching leads to thickness non-uniformities in the final device, which strongly impacts the control of its optical performance.

### SUMMARY OF THE INVENTION

There exists a need to improve existing optoelectronic devices comprising a plurality of gallium nitride diodes and a circuit for controlling these diodes. There also exists a need to overcome all or part of the disadvantages of existing methods of manufacturing such devices.

For this purpose, an embodiment provides a method of manufacturing an optoelectronic device, the method comprising the following successive steps:
a) forming, on a support substrate, an electropolishing stack comprising:
   a first sacrificial semiconductor layer;
   a second charge transport semiconductor layer; and
   a third semiconductor layer for protecting the second layer, the third layer being interposed between the first and second layers and having a doping level lower than those of the first and second layers;
b) forming, on the side of a surface of the electropolishing stack opposite to the support substrate, an active gallium nitride diode stack; and
c) removing the support substrate by electropolishing of the first layer by applying, between an electrode in contact with the second or the third layer and a counter-electrode arranged in an electrolytic solution, a bias current flowing through, in this order, the second, third, and first layers.

According to an embodiment, the method further comprises, subsequently to step c), a step of forming, inside and on top of the active gallium nitride diode stack, of a plurality of individual diodes.

According to an embodiment, the method further comprises, between steps b) and c), a step d) of transfer of the active gallium nitride diode stack and of the electropolishing stack onto a control circuit.

According to an embodiment, the method further comprises, between steps b) and d), a step of forming, inside and on top of the gallium nitride active diode stack, of a plurality of individual diodes.

According to an embodiment, the first layer is located on top of and in contact with a surface of the third layer opposite to the support substrate.

According to an embodiment, the method further comprises, prior to step c), a step of forming of trenches extending through the support substrate and forming, in top view, a grid.

According to an embodiment, the method further comprises, subsequently to the forming of the trenches, a step of forming of vias located at the intersections of the grid, the vias extending through the second and third layers and terminating within the thickness of the first layer.

According to an embodiment, the second layer is located on top of and in contact with a surface of the third layer opposite to the support substrate.

According to an embodiment, the method further comprises, prior to step c), a step of forming of trenches and/or of vias extending through the support substrate and terminating within the thickness of the first layer.

According to an embodiment, the method further comprises, subsequently to step c), a step of forming of microlenses in the second and third layers.

According to an embodiment, the first layer has a doping level at least ten times higher than that of the third layer.

According to an embodiment:
the first and second layers each have a doping level equal to approximately 1.10¹⁹ at.cm⁻³; and
the third layer has a doping level equal to approximately 1.10¹⁶ at.cm⁻³.

According to an embodiment, the active gallium nitride diode stack is an active light-emitting gallium nitride diode stack.

According to an embodiment, the gallium nitride active diode stack is an active photosensitive gallium nitride diode stack.

According to an embodiment, the electropolishing stack further comprises a fourth transition semiconductor layer interposed between the support substrate and the first layer.

According to an embodiment, the method further comprises, prior to step a), a step of forming, on the support substrate, of a buffer stack comprising at least one layer for matching the lattice constant and the thermal expansion coefficient.

### BRIEF DESCRIPTION OF THE DRAWINGS

These features and advantages, as well as others, will be described in detail in the following description of specific embodiments, which is provided by way of example and is not intended to be limiting, in connection with the accompanying drawings, in which:

FIG. 1A, FIG. 1B, FIG. 1C, FIG. 1D, FIG. 1E, and FIG. 1F are side and cross-section views, simplified and partial, of examples of structures obtained at the end of successive steps of a method of manufacturing an optoelectronic device according to an embodiment;

FIG. 2 is a side and cross-section view, simplified and partial, of an example of a structure obtained at the end of a step of a variant of the method of FIGS. 1A to 1F;

FIG. 3A, FIG. 3B, FIG. 3C, FIG. 3D, FIG. 3E, and FIG. 3F are side and cross-section views, simplified and partial, of examples of structures obtained at the end of successive steps of a method of manufacturing an optoelectronic device according to an embodiment;

FIG. 4A, FIG. 4B, and FIG. 4C are side and cross-section views, simplified and partial, of examples of structures obtained at the end of successive steps of a method of manufacturing an optoelectronic device according to an embodiment;

FIG. 5 is a top view, simplified and partial, of the structure of FIG. 1D; and

FIG. 6 is a graph representing variations in pore size and density within a gallium nitride layer, as a function of a doping level and of a bias voltage applied to said layer.

### DESCRIPTION OF EMBODIMENTS

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail. In particular, the various applications of the optoelectronic devices of the present disclosure, particularly the various devices likely to incorporate such devices, have not been detailed, the described embodiments being compatible with all or most usual applications and with all or most usual devices implementing at least one optoelectronic device, subject to possible adaptations within the abilities of those skilled in the art upon reading of the present disclosure.

Further, the implementation of an integrated gallium nitride diode control circuit has not been detailed, the described embodiments being compatible with usual structures and methods of manufacturing of such control circuits. Further, the composition and the arrangement of the different layers of an active gallium nitride diode stack have not been detailed, the described embodiments being compatible with common active gallium nitride diode stacks.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

Unless otherwise specified, the terms “insulating” and “conductive” respectively mean electrically insulating and electrically conductive.

Unless otherwise specified, the expression “in contact with” means “in mechanical contact with.”

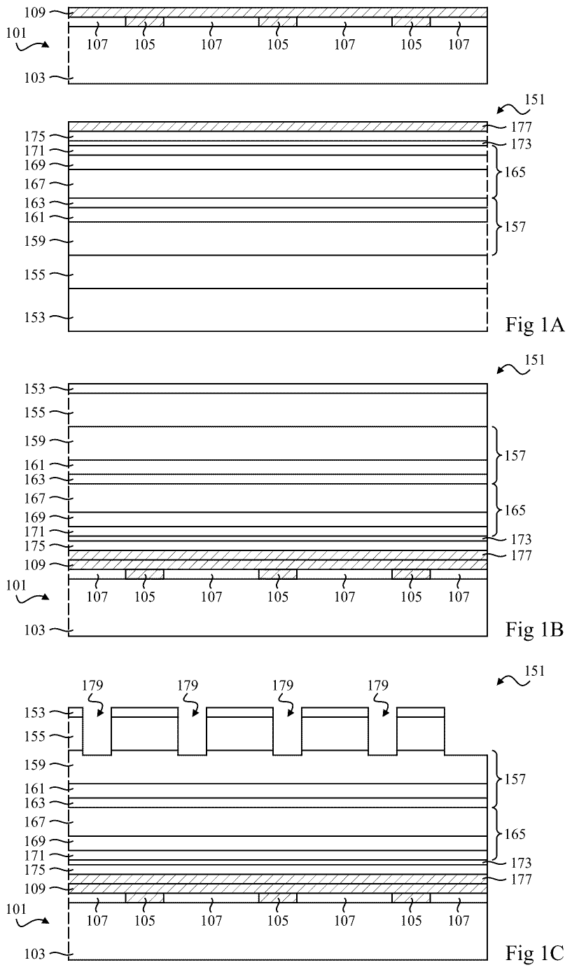

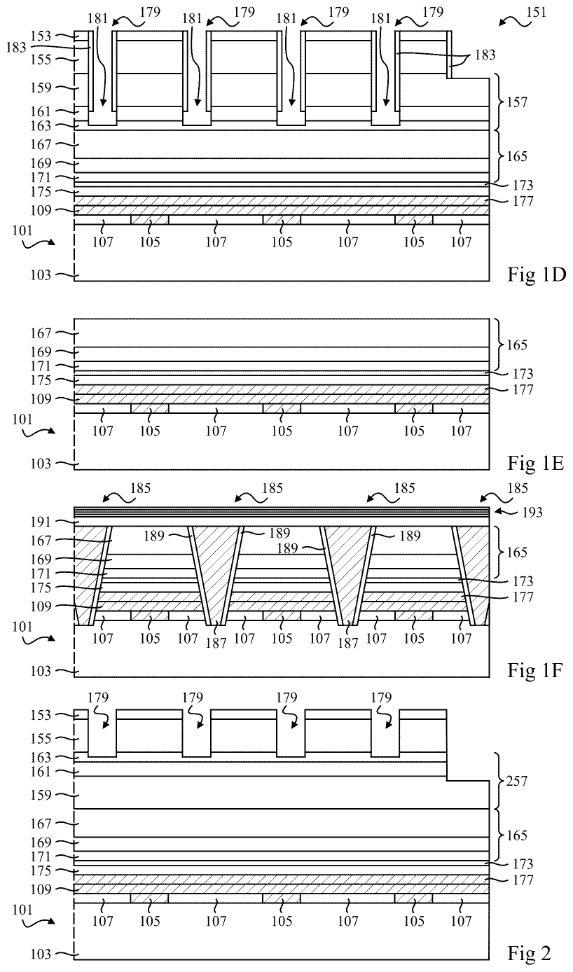

FIG. 1A, FIG. 1B, FIG. 1C, FIG. 1D, FIG. 1E, and FIG. 1F are side and cross-section views, simplified and partial, of examples of structures obtained at the end of successive steps of a method of manufacturing an optoelectronic device comprising a plurality of gallium nitride (GaN) diodes according to an embodiment.

FIG. 1A schematically shows an integrated control circuit 101 previously formed inside and on top of a substrate 103. Substrate 103 is, for example, a wafer or a piece of wafer made of a semiconductor material, for example, silicon.

In the shown example, control circuit 101 comprises, on its upper surface side, for each of the diodes of the device, a metal connection pad 105 intended to be connected to one of the electrodes (anode or cathode) of the diode. In the case of a light-emitting diode (LED), metal connection pad 105 enables, for example, to control a current flowing through the LED and/or to apply a voltage across the LED. Control circuit 101 comprises, for example, for each LED, an elementary control cell connected to the metal pad 105 dedicated to the LED and comprising one or more transistors enabling to control the current flowing through the LED and/or the voltage applied across the LED. Control circuit 101 is, for example, implemented in CMOS (Complementary Metal-Oxide-Semiconductor) technology. As an example, the control circuit is of ASIC (Application-Specific Integrated Circuit) type.

Metal pads 105 may be laterally surrounded by an insulating material 107, for example silicon oxide, so that control circuit 101 has a substantially flat upper surface comprising an alternation of metal regions 105 and of insulating regions 107. The contact on the electrodes of the LEDs (cathodes or anodes) not connected to pads 105 may be made collectively, for example in a peripheral region of control circuit 101, via one or more connection pads (not shown in the drawing) of control circuit 101.

In the shown example, a metal layer 109 coats substantially the entire upper surface of control circuit 101. In particular, metal layer 109 is in contact with the metal connection pads 105 of control circuit 101.

FIG. 1A further shows, schematically, a structure 151 formed on a support substrate 153. Support substrate 153 is, for example, a wafer or a piece of wafer made of silicon, sapphire, corundum, or any other material on which an active gallium nitride diode stack can be formed.

In the shown example, structure 151 comprises a buffer layer 155 coating the upper surface of support substrate 153. In the shown example, buffer layer 155 is located on top of and in contact with the upper surface of support substrate 153. As an example, buffer layer 155 is made of aluminum nitride (AlN) or aluminum gallium nitride (AlGaN). Buffer layer 155 has, for example, a thickness in the order of several hundred nanometers. Although FIG. 1A illustrates an example in which structure 151 comprises a single buffer layer 155, this example is not limiting, and structure 151 may, as a variant, comprise any number of buffer layers arranged on the upper surface of support substrate 153.

In the shown example, structure 151 further comprises an electropolishing stack 157 located on support substrate 153. In the shown example, electropolishing stack 157 coats buffer layer 155.

In the shown example, electropolishing stack 157 comprises:
a charge transport layer 159 located on top of and in contact with the upper surface of buffer layer 155;
a layer 161 for protecting layer 159 located on top of and in contact with the upper surface of layer 159; and
a sacrificial layer 163 located on top of and in contact with the upper surface of layer 161.

Each layer 159, 161, 163 is, for example, based on a semiconductor material, for example GaN.

Layer 159 is, for example, made of heavily doped n-type GaN (n-GaN). For example, layer 159 has a doping level equal to approximately 1.10¹⁹at.cm⁻³. Layer 159 has, for example, a thickness equal to approximately 1 μm.

Layer 161, for example, is made of intrinsic GaN, that is, unintentionally doped GaN (UID, for “unintentionally doped”, GaN or NID, for “non-intentionally doped”, GaN). For example, layer 161 has a residual donor concentration in the range from 10¹⁵ to 10¹⁸ at.cm⁻³, for example in the order of 10¹⁷ at.cm⁻³. Layer 161 has a thickness in a range from 200 to 500 nm.

Layer 163 is, for example, made of heavily-doped n-type GaN. As an example, layer 159 has a doping level lower than or equal to that of layer 163. The doping level of layer 163 is, in particular, much higher, for example at least ten times higher, than that of layer 161. Layer 163 has, for example, a doping level equal to approximately 1.10¹⁹ at.cm⁻³. Layer 163 has a thickness smaller than that of layer 159, for example in the order of a few tens of or a few hundred nanometers. As an example, the thickness of layer 163 is in a range from 20 to 500 nm.

Although this has not been shown in FIG. 1A, electropolishing stack 157 may further comprise a transition layer interposed between buffer layer 155 and charge transport layer 159. In this case, the transition layer has, for example, a multilayer structure comprising a layer of carbon-doped GaN (GaN:C) coating buffer layer 155 and another UID GaN layer coating the GaN:C layer. As an example, the GaN:C layer has a doping level in the order of 10¹⁸ at.cm⁻³. The GaN:C layer has, for example, a thickness in a range from 100 to 500 nm. As an example, the UID GaN layer has a doping level in the order of 1.10¹⁶ at.cm⁻³. The UID GaN layer, for example, has a thickness in a range from 100 to 500 nm. The transition layer for example enables to decrease the surface roughness prior to the growth of layer 159. It for example further enables to manage the stress present in layer 159.

In the shown example, structure 151 further comprises an active GaN diode stack 165, for example an active GaN LED stack, arranged above support substrate 153, on electropolishing stack 157. In the shown example, active stack 165 comprises, in the order from the upper surface of electropolishing stack 157, an n-type doped gallium nitride layer 167, an active layer 169—for example, an emissive layer, in the case of an active LED stack—and a layer of p-type doped gallium nitride 171. Active layer 169 is, for example, formed of a stack of one or more active layers, each forming a quantum well, for example based on GaN, InN, InGaN, AlGaN, AlN, AlInGaN, GaP, AlGaP, AlInGaP, or a combination of one or more of these materials. As a variant, active layer 169 may be a layer of intrinsic gallium nitride, having, for example, a residual donor concentration in the range from 10¹⁵ and 10¹⁸ at.cm⁻³, for example in the order of 10¹⁷ at.cm⁻³.

In the shown example, the lower surface of active layer 169 is in contact with the upper surface of layer 167, and the upper surface of active layer 169 is in contact with the lower surface of layer 171.

In the shown example, buffer layer 155 enables to form an interface between support substrate 153 and gallium nitride layer 167. Although this has not been shown, other buffer layers may be provided between support substrate 153 and active diode stack 165. The layers 167, 169, and 171 of active diode stack 165 are, for example, formed by epitaxy from the upper surface of electropolishing stack 157, buffer layer 155 then enabling to perform a matching of the lattice constant and of the thermal expansion coefficient between support substrate 153 and active diode stack 165.

In the example illustrated in FIG. 1A, structure 151 further comprises a transparent conductive layer 173 coating active diode stack 165. In the shown example, conductive layer 173 is located on top of and in contact with the upper surface of layer 171. Conductive layer 173 acts, for example, as an upper electrode in contact with p-type doped layer 171.

In the shown example, structure 151 further comprises a mirror layer 175 coating conductive layer 173. In the shown example, mirror layer 175 is located on top of and in contact with the upper surface of conductive layer 173. The mirror layer is, for example, a metal layer reflective in a wavelength range of emission of active diode stack 165, in the case where stack 165 is an active LED stack.

Further, in this example, structure 151 comprises a metal layer 177 coating mirror layer 175. Metal layer 177 is, for example, located on top of and in contact with the upper surface of mirror layer 175. Metal layer 177 coats, for example, substantially the entire upper surface of active stack 165. As an example, metal layer 177 is made of the same material as metal layer 109.

FIG. 1B shows a structure obtained at the end of a subsequent step of transfer of active GaN diode stack 165 and of electropolishing stack 157 onto the upper surface of control circuit 101. For this purpose, the assembly comprising support substrate 153 and structure 151 is, for example, turned over and then placed on control circuit 101, so as to bring the upper surface (in the orientation of FIG. 1A) of metal layer 177 into contact with the upper surface of metal layer 109. During this step, active stack 165 is bonded to control circuit 101. As an example, the bonding of active stack 165 to control circuit 101 may be obtained by molecular bonding between the two surfaces brought into contact. As a variant, the bonding of the two surfaces may be performed by thermocompression, hybrid bonding, or any other suitable bonding method.

FIG. 1B further illustrates a subsequent step of thinning of support substrate 153, for example by grinding. In the shown example, a portion of support substrate 153 remains on the upper surface of buffer layer 155 at the end of this step. This example is however not limiting, and support substrate 153 may, as a variant, be completely removed during this step.

FIG. 1C shows a structure obtained at the end of a subsequent step of forming of trenches 179 on the upper surface side of the structure of FIG. 1B.

In the shown example, the trenches extend vertically from a surface of support substrate 153 opposite to active diode stack 165 (the upper surface of support substrate 153, in the orientation of FIG. 1C), through support substrate 153 and buffer layer 155, and terminate within the thickness of layer 159. Trenches 179 are, for example, arranged so as to have, in top view, the shape of a grid.

In the shown example, portions of support substrate 153 and buffer layer 155 are further removed in a peripheral region of the structure (on the right-hand side of the structure, in the orientation of FIG. 1C). This region has, for example, the shape of a ring, in the case where substrate 103 is a wafer of substantially circular shape.

As a variant, the forming of trenches 179 may be omitted, and only the portions of support substrate 153 and of the buffer layer of the peripheral region of the structure are removed. This enables to access the upper surface of layer 159 in order to make an electrical contact located at the edge of the wafer.

FIG. 1D shows a structure obtained at the end of a subsequent step of forming of vias 181 from the upper surface of the structure of FIG. 1C.

In the shown example, vias 181 extend vertically, through the layers 159 and 161 of electropolishing stack 157, and terminate within the thickness of layer 163. Vias 181 are for example located at the intersections of the grid formed by trenches 179.

In the shown example, the walls of vias 181 are at least partially coated with an insulating layer 183. Insulating layer 183 for example completely coats the lateral surfaces of layer 159 exposed inside each trench 179 and each via 181. This enables to passivate layer 159 in view of a subsequent step of electropolishing of sacrificial layer 163. Insulating layer 183 for example further completely covers the lateral surfaces of support substrate 153 and of buffer layer 155, and, for example, partially coats the lateral surfaces of layer 161 exposed inside each trench 179 and each via 181. In the shown example, insulating layer 183 does not coat the bottom of vias 181. As a variant, insulating layer 183 may be omitted, for example in a case where sacrificial layer 163 has a doping level at least ten times higher than that of layer 159.

FIG. 1E shows a structure obtained at the end of a subsequent step of removal of support substrate 153, buffer layer 155, and stack 157 by electropolishing of sacrificial layer 163.

For this purpose, the structure of FIG. 1D is, for example, immersed in a bath containing an electrolytic solution, and a potential is for example applied between an electrode in contact with layer 159, located, for example, in the peripheral region of the structure, and a counter-electrode immersed in the electrolytic solution. The electrode in contact with layer 159 is, for example, located on top of and in contact with a portion of the upper surface of layer 159 not coated with layer 155 (on the right-hand side of the structure, in the orientation of FIG. 1D). As a variant, the electrode is in contact with layer 161, the electrode then being for example located on top of and in contact with a portion of the upper surface of layer 161 not coated with layer 159. Further, the counter-electrode is for example located above the structure of FIG. 1D. The electrolytic solution in which the structure is immersed penetrates trenches 179 and vias 181. This enables to bring the electrolytic solution into contact with layer 163.

During the application of the potential, a bias current flowing from the electrode in contact with layer 159 or 161 to the counter-electrode flows through, in this order, layer 159, layer 161, and layer 163. The bias current causes a removal of sacrificial layer 163 by electropolishing. This leads to dissociating active diode stack 165 from the buffer layer 155 coating support substrate 153.

During this step, insulating layer 183 enables to prevent the electrolytic solution from coming into contact with layer 159 inside vias 181.

FIG. 1F shows a structure obtained at the end of a subsequent step of forming of contacting elements 185.

In the shown example, each contacting element 185 comprises a conductive region 187 having its flanks coated with an insulating layer 189. In the orientation of FIG. 1F, each conductive region 187 extends vertically from the upper surface of active diode stack 165, through layers 167, 169, 171, 173, 175, 177, and 109 and through insulating regions 107, all the way into control circuit 101. Conductive region 187 is, for example, in electrical contact with lower metal levels of the control circuit (not shown), in order to provide an electrical connection of the cathode of the associated LED.

FIG. 1F further illustrates a subsequent step of deposition of a transparent conductive layer 191 and a reflective structure 193 on the upper surface side of the structure. In the shown example, conductive layer 191 is located on top of and in contact with the upper surface of layer 167 and with the upper surfaces of the conductive regions 187 of contacting elements 185. Layer 191 forms, for example, a cathode electrode common to the diodes of the device.

As an example, reflective structure 193 is a Bragg grating, or distributed Bragg reflector (DBR).

FIG. 2 is a side and cross-section view, simplified and partial, of an example of a structure obtained at the end of a step of a variant of the method of FIGS. 1A to 1F.

The structure of FIG. 2 has elements in common with the structure of FIG. 1C. These common elements will not be detailed again hereafter. The structure of FIG. 2 differs from that of FIG. 1C in that it comprises an electropolishing stack 257 similar to the electropolishing stack 157 of FIG. 1C, but in which the order of layers 159, 161, and 163 is reversed. More precisely, in the orientation of FIG. 2, layer 159 is located on top of and in contact with the upper surface of layer 167 of active diode stack 165, and layer 163 is located under and in contact with the lower surface of buffer layer 155, layer 161 being interposed between layers 159 and 163.

The structure of FIG. 2 is obtained, for example, by the implementation of steps similar to those previously described in relation with FIGS. 1A and 1C, by replacing electropolishing stack 157 with electropolishing stack 257. Steps similar to those previously described in relation with FIGS. 1D to 1F are then carried out, for example, starting from the structure of FIG. 2. In particular, vias similar to vias 181 may be formed in the structure of FIG. 2 at the intersections of the grid formed by trenches 179. As a variant, vias 181 may be omitted. As a variant, only vias 181 may be formed, trenches 179 then being omitted.

In this variant, insulating layer 183 is omitted, for example.

Methods of manufacturing optoelectronic devices in which the individual diodes are formed after transfer of the active diode stack to the control circuit have been described in relation with FIGS. 1A to 1F and FIG. 2. As a variant, the individual diodes may be formed before transfer of the active diode stack to the control circuit, for example as described hereafter.

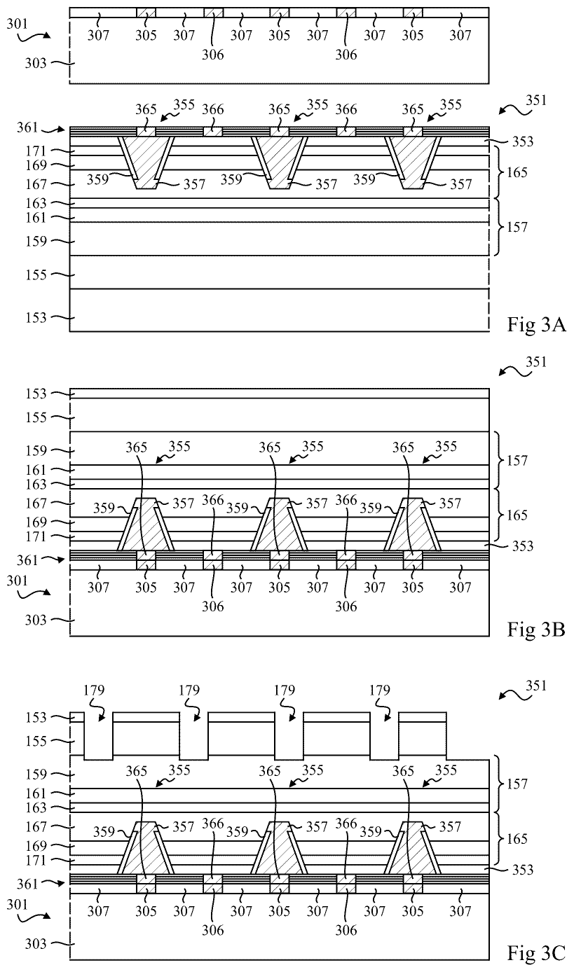

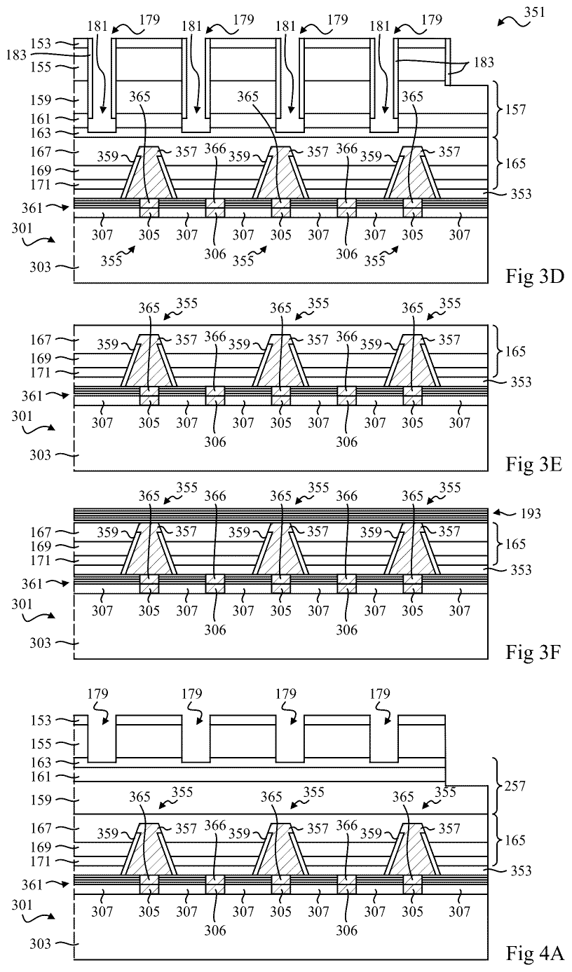

FIG. 3A, FIG. 3B, FIG. 3C, FIG. 3D, FIG. 3E, and FIG. 3F are side and cross-section views, simplified and partial, of examples of structures obtained after successive steps of a method of manufacturing an optoelectronic device according to an embodiment.

FIG. 3A schematically shows an integrated control circuit 301 previously formed inside and on top of a substrate 303. Substrate 303 is, for example, similar or identical to the substrate 103 previously described in relation with FIG. 1A. In the shown example, control circuit 301 comprises, on its upper surface side, for each of the diodes of the device, a metal connection pad 305 intended to be connected to one of the electrodes (anode or cathode) of the diode and another metal connection pad 306 intended to be connected to the other electrode of the diode. In the case of a light-emitting diode (LED), metal connection pads 305 and 306 enable, for example, to control a current flowing through the LED and/or to apply a voltage across the LED. Control circuit 301 comprises, for example, for each LED, an elementary control cell connected to the metal pads 305 and 306 dedicated to the LED and comprising one or more transistors enabling to control the current flowing through the LED and/or the voltage applied across the LED. Control circuit 301 is, for example, implemented in CMOS technology. Metal pads 305 and 306 may be laterally surrounded by an insulating material 307, for example silicon oxide, so that control circuit 301 has a substantially planar upper surface comprising an alternation of metal regions 305, 306 and of insulating regions 307.

In the shown example, unlike the control circuit 101 of FIG. 1A, control circuit 301 comprises no metal layer coating its upper surface.

FIG. 3A further schematically shows a structure 351 formed on the support substrate 153 previously described in relation with FIG. 1A.

The structure 351 of FIG. 3A comprises elements in common with the structure 151 of FIG. 1A. These common elements will not be detailed again hereafter.

The structure 351 of FIG. 3A differs from the structure 151 of FIG. 1A in that structure 351 comprises, in addition to buffer layer 155, electropolishing stack 157 and active diode stack 165, a transparent conductive layer 353 coating the upper surface of layer 171. Transparent conductive layer 353 is, for example, similar or identical to the transparent conductive layer 191 previously described in relation with FIG. 1F.

In the shown example, structure 351 further comprises contacting elements 355 flush with the upper surface of conductive layer 353.

In the shown example, each contacting element 355 comprises a conductive region 357 having its flanks coated with an insulating layer 359. In the orientation of FIG. 3A, each conductive region 357 extends vertically from the upper surface of conductive layer 353, through layers 353, 171, and 169, and terminates within the thickness of layer 167.

In the shown example, the structure 351 further comprises a reflective structure 361 coating the upper surface of conductive layer 353 and the upper surfaces of contacting elements 355. As an example, reflective structure 361 is similar or identical to the reflective structure 193 previously described in relation with FIG. 1F.

In the shown example, structure 351 further comprises metal connection pads 365 and 366 formed in reflective structure 193. Each metal connection pad 365 is in contact, by its lower surface, with the upper surface of the conductive region 357 of the underlying contacting element 355. Further, each metal connection pad 366 is in contact, by its lower surface, with the upper surface of conductive layer 353. The metal connection pads 365 and 366 of structure 351 are intended to be brought into contact with the metal pads 305 and 306, respectively, of control circuit 301. In the shown example, metal pads 365 and 366 respectively form the cathode and anode contacts of the diodes.

FIG. 3B shows a structure obtained at the end of a subsequent step of transfer of active GaN diode stack 165 and of electropolishing stack 157 onto the upper surface of control circuit 301. For this purpose, the assembly comprising support substrate 153 and structure 351 is, for example, turned over and then transferred onto control circuit 301, so as to bring the upper surfaces (in the orientation of FIG. 3A) of metal connection pads 365 and 366 into contact with the upper surfaces of metal connection pads 305 and 306, respectively. During this step, active stack 165 is bonded to control circuit 301. As an example, the bonding of active stack 165 to control circuit 301 may be obtained by molecular bonding between the two surfaces brought into contact. As a variant, the bonding of the two surfaces may be performed by thermocompression, hybrid bonding, or any other suitable bonding method.

FIG. 3B further illustrates a subsequent step of thinning of support substrate 153, for example by grinding. In the shown example, a portion of support substrate 153 remains on the upper surface of buffer layer 155 at the end of this step. This example is however not limiting, and support substrate 153 may, as a variant, be completely removed during this step.

FIG. 3C shows a structure obtained at the end of a subsequent step of forming of trenches 179 on the upper surface side of the structure of FIG. 3B, for example similarly to what has been previously described in relation with FIG. 1C.

FIG. 3D shows a structure obtained at the end of a subsequent step of forming of vias 181 from the upper surface of the structure of FIG. 3C and of forming of insulating layer 183, for example similarly to what has been previously described in relation with FIG. 1D.

FIG. 3E shows a structure obtained at the end of a subsequent step of removal of support substrate 153, buffer layer 155, and stack 157 by electropolishing of sacrificial layer 163, for example similarly to what has been described hereabove in relation with FIG. 1E.

FIG. 3F shows a structure obtained at the end of a subsequent step of thinning of layer 167 so that the conductive regions 357 of contacting elements 355 are flush with the upper surface of layer 167. Further, during this step, reflective structure 193 is deposited on the upper surface side of layer 167.

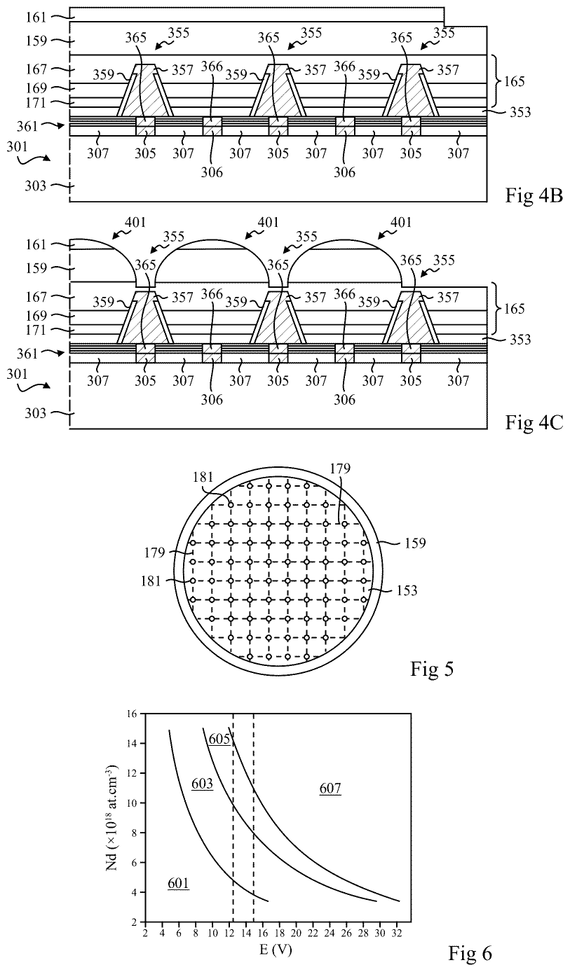

FIG. 4A, FIG. 4B, and FIG. 4C are side and cross-section views, simplified and partial, of examples of structures obtained at the end of successive steps of a method of manufacturing an optoelectronic device according to an embodiment.

FIG. 4A is a side and cross-section view, simplified and partial, of an example of a structure obtained at the end of a step of a variant of the method of FIGS. 3A to 3F.

The structure of FIG. 4A has elements in common with the structure of FIG. 3C. These common elements will not be described in detail again hereafter. The structure of FIG. 4A differs from that of FIG. 3C in that it comprises, instead of electropolishing stack 157, the electropolishing stack 257 described hereabove in relation with FIG. 2. More precisely, in the orientation of FIG. 4A, layer 159 is located on top of and in contact with the upper surface of layer 167 of active diode stack 165, and layer 163 is located under and in contact with the lower surface of buffer layer 155, layer 161 being interposed between layers 159 and 163.

The structure of FIG. 4A is obtained, for example, by the implementation of steps similar to those previously described in relation with FIGS. 3A and 3C, by replacing electropolishing stack 157 with electropolishing stack 257.

FIG. 4B shows a structure obtained at the end of a subsequent step of removal of support substrate 153 and of layers 155 and 163 by electropolishing of sacrificial layer 163, for example similarly to what has been described hereabove in relation with FIG. 1E.

FIG. 4C shows a structure obtained at the end of a subsequent step of forming of microlenses 401 in the layers 159 and 161 of electropolishing stack 257 remaining after the removal of sacrificial layer 163.

In the shown example, microlenses 401 are formed vertically in line with portions of active layer 169 located opposite metal connection pads 366.

FIG. 5 is a top view, simplified and partial, of the structure of FIG. 1D.

In the shown example, dotted vertical and horizontal lines symbolize the trenches 179 extending from the upper surface of support substrate 153 and forming a grid, and solid circles symbolize the vias 181 located substantially at the intersections of trenches 179.

The peripheral ring formed by the uncoated portion of layer 159 allows, for example, contact with an electrode intended to apply the bias potential used to remove sacrificial layer 163 by electropolishing.

FIG. 6 is a graph showing variations in pore size and density within a GaN layer, for example sacrificial layer 163, as a function of a doping level Nd (expressed in atoms per cubic centimeter, at.cm⁻³, the values indicated on the y-axis having to be multiplied by 10¹⁸) and a bias voltage E (in volts, V) applied to said layer.

In the shown example, the graph comprises:
a pre-breakdown region 601 in which the crystal structure of the layer starts degrading at the location of the defects present in this structure;
a porosification region 603, in which pores form inside the layer without, however, significantly decreasing the mechanical cohesion of the layer;
an electropolishing limit region 605, in which a beginning of degradation of the mechanical cohesion of the layer by the grouping of adjacent pores can be observed; and
an electropolishing region 607, in which the layer is removed, or etched, under the effect of the application of bias voltage E.

In the case where sacrificial layer 163 is made of GaN, a doping level Nd higher than or equal to approximately 1.1×10¹⁹ at.cm⁻³ and a voltage E applied to layer 163 in a range from 12 to 14 V, for example, enable to implement the steps of electropolishing of sacrificial layer 163 previously described in relation with FIGS. 1E, 3E, and 4B. In this case, protective layer 161 has, for example, a doping level lower than or equal to approximately 4.10¹⁸ at.cm⁻³, which enables layer 161 to remain in pre-breakdown region 601.

The thickness of sacrificial layer 163 is selected to be the lowest possible, so that the electropolishing, and therefore the removal, of this layer is as fast as possible, while still being sufficiently thick to allow the etching of vias 181 and/or trenches 179, so that these vias and/or trenches emerge into layer 163.

The thickness of protective layer 161 is selected so that layer 161 is sufficiently thin to allow good charge transfer from charge transport layer 159, and sufficiently thick to remain intact during the step of electropolishing of sacrificial layer 163.

The thickness of charge transport layer 159 is selected so that layer 159 is sufficiently thin not to degrade the crystalline quality of the layers of active stack 165, and sufficiently thick to remain intact during the step of electropolishing of sacrificial layer 163, to avoid edge effects in the event that support substrate 153 has a diameter greater than or equal to 200 mm, and to allow good charge conduction.

An advantage of the above-described embodiments is that they allow better control of the thickness of the layers 167, 169, and 171 of active diode stack 165 as compared with existing methods of manufacturing optoelectronic devices comprising a plurality of gallium nitride diodes and a circuit for controlling these diodes. This enables, for example, to form optical cavities suitable for the manufacturing of devices of resonant-cavity LED (RC LED) type or of VCSEL (vertical-cavity surface-emitting laser) type.

Further, an advantage of the embodiments of the present disclosure is that they enable to simplify the removal of the support substrate on which active diode stack 165 or the individual diodes are formed, depending on the retained approach.

Various embodiments and variants have been described. Those skilled in the art will understand that certain features of these various embodiments and variants could be combined, and other variants will become apparent to those skilled in the art. Further, although the above-described embodiments take as an example the case where active diode stack 165 is an active LED stack, these embodiments can be transposed by those skilled in the art to cases where the active diode stack is of any type, for example an active photosensitive diode stack, for example a GaN-based photodiode stack. In this case, metal pads 365 and 366 respectively form the anode and cathode contacts of the photodiodes.

Finally, the practical implementation of the described embodiments and variants is within the abilities of those skilled in the art based on the functional indications given hereabove. In particular, those skilled in the art are capable, based on the indications of the present disclosure, of choosing to use electropolishing stack 157 or electropolishing stack 257, for example depending on the desired residual GaN thickness. In particular, electropolishing stack 157 is preferred when components with a low, well-controlled residual GaN thickness, typically less than 1 μm, preferably less than 500 nm, are desired to be formed, as is the case in the RC-LED type structures described in relation with FIGS. 1F and 3F or in VCSEL type structures. On the contrary, when devices with a high residual GaN thickness, typically higher than 1 μm, preferably higher than 2 μm, are desired to be formed, the selection of electropolishing stack 257 is preferred. The thicknesses of layers 159 and 161 enable to refine the target thickness values.

Further, the described embodiments are not limited to the specific examples of materials and of dimensions mentioned in the present disclosure.

1. Method of manufacturing an optoelectronic device, the method comprising the following successive steps:
a) forming, on a support substrate, an electropolishing stack comprising:
a first sacrificial semiconductor layer;
a second charge transport semiconductor layer; and
a third semiconductor layer for protecting the second layer, the third layer being interposed between the first and second layers and having a doping level lower than those of the first and second layers;
b) forming, on the side of a surface of the electropolishing stack opposite to the support substrate, an active gallium nitride diode stack; and
c) removing the support substrate by electropolishing of the first layer by applying, between an electrode in contact with the second or the third layer and a counter-electrode arranged in an electrolytic solution, a bias current flowing through, in this order, the second, third, and first layers.

2. Method according to claim 1, further comprising, subsequently to step c), a step of forming, inside and on top of the active gallium nitride diode stack, of a plurality of individual diodes.

3. Method according to claim 1, further comprising, between steps b) and c), a step d) of transfer of the active gallium nitride diode stack and of the electropolishing stack onto a control circuit.

4. Method according to claim 3, further comprising, between steps b) and d), a step of forming, inside and on top of the active gallium nitride diode stack, of a plurality of individual diodes.

5. Method according to claim 1, wherein the first layer is located on top of and in contact with a surface of the third layer opposite to the support substrate.

6. Method according to claim 5, further comprising, prior to step c), a step of forming of trenches extending through the support substrate and forming, in top view, a grid.

7. Method according to claim 6, further comprising, after the forming of the trenches, a step of forming of vias located at the intersections of the grid, the vias extending through the second and third layers and terminating within the thickness of the first layer.

8. Method according to claim 1, wherein the second layer is located on top of and in contact with a surface of the third layer opposite to the support substrate.

9. Method according to claim 8, further comprising, prior to step c), a step of forming of trenches and/or of vias extending through the support substrate and terminating within the thickness of the first layer.

10. Method according to claim 8, further comprising, subsequently to step c), a step of forming of microlenses in the second and third layers.

11. Method according to claim 1, wherein the first layer has a doping level at least ten times higher than that of the third layer.

12. Method according to claim 11, wherein:
the first and second layers each have a doping level equal to approximately 1.10¹⁹ at.cm⁻³; and
the third layer has a doping level equal to approximately 1.10¹⁶ at.cm⁻³.

13. Method according to claim 1, wherein the active gallium nitride diode stack is an active gallium nitride light-emitting diode stack.

14. Method according to claim 1, wherein the active gallium nitride diode stack is an active gallium nitride photosensitive diode stack.

15. Method according to claim 1, wherein the electropolishing stack further comprises a fourth transition semiconductor layer interposed between the support substrate and the first layer.

16. Method according to claim 1, further comprising, prior to step a), a step of forming, on the support substrate, of a buffer stack comprising at least one layer for matching the lattice constant and the thermal expansion coefficient.
